(19) United States
(12) Patent Application Publication
(10) Pub. No.: US 2025/0210588 A1
(43) Pub. Date: Jun. 26, 2025

(54) MEMORY SYSTEM AND SEMICONDUCTOR STORAGE DEVICE

(71) Applicant: Kioxia Corporation, Tokyo (JP)

(72) Inventor: Yuichi SANO, Setagaya Tokyo (JP)

(73) Assignee: Kioxia Corporation, Tokyo (JP)

(21) Appl. No.: 18/828,056

(22) Filed: Sep. 9, 2024

(30) Foreign Application Priority Data
Dec. 21, 2023 (JP) 2023-215798

(51) Int. Cl. H01L 25/065; H01L 23/31; H01L 23/498; H01L 25/18; H10B 80/00

(52) U.S. Cl. CPC H01L 25/0652; H01L 23/3114; H01L 23/49816; H01L 25/18; H10B 80/00; H01L 2225/06506

(57) ABSTRACT

A memory system according to an embodiment includes a first board, a control circuit, and a semiconductor storage device. The semiconductor storage device includes a second board, a plurality of semiconductor memory chips, and a plurality of connection terminals. Each of the plurality of semiconductor memory chips includes only a plurality of first terminals for one channel configured of a predetermined number of terminals. The plurality of first terminals serve as terminals capable of transferring data signals or timing signals. The plurality of connection terminals include only a plurality of second terminals for one channel configured of the predetermined number of terminals. The plurality of second terminals serve as terminals capable of transferring the data signals or the timing signals.

### CROSS-REFERENCE TO RELATED APPLICATION

This application is based upon and claims the benefit of priority from Japanese Patent Application No. 2023-215798, filed Dec. 21, 2023; the entire contents of which are incorporated herein by reference.

### FIELD

Embodiments of the present invention relate to a memory system and a semiconductor storage device.

### BACKGROUND ART

A memory system including a board, a controller mounted on the board, and a semiconductor storage device mounted on the board is known.

### BRIEF DESCRIPTION OF THE DRAWINGS

FIG. 1 is a perspective view showing a memory system according to a first embodiment.

FIG. 2 is a diagram showing a connection relationship between a controller and a NAND package according to the first embodiment.

FIG. 3 is a cross-sectional view showing the NAND package according to the first embodiment.

FIG. 4 is a plan view showing a NAND package according to the first embodiment.

FIG. 5 is a bottom view showing the NAND package according to the first embodiment.

FIG. 6 is a cross-sectional view taken along line F6-F6 of the memory system shown in FIG. 1.

FIG. 7 is a cross-sectional view showing a memory system of a comparative example.

FIG. 8 is a bottom view showing a NAND package according to a first modified example of the first embodiment.

FIG. 9 is a cross-sectional view showing a NAND package according to a second modified example of the first embodiment.

FIG. 10 is a cross-sectional view showing a NAND package according to a third modified example of the first embodiment.

FIG. 11 is a cross-sectional view showing a NAND package according to a second embodiment.

FIG. 12 is a cross-sectional view showing an enlarged area surrounded by a line F12 shown in FIG. 11.

### DETAILED DESCRIPTION

A memory system according to one embodiment includes a first board, a control circuit, and a semiconductor storage device. The control circuit is on the first board. The semiconductor storage device is on the first board. The semiconductor storage device includes a second board, a sealing member, a plurality of semiconductor memory chips, a plurality of bonding wires, and a plurality of connection terminals. The second board includes a first surface, and a second surface on the side opposite to the first surface. The sealing member covers the first surface when viewed from a thickness direction of the second board. The plurality of semiconductor memory chips are between the first surface and the sealing member. The plurality of bonding wires connect the first surface to the plurality of semiconductor memory chips. The plurality of connection terminals are on the second surface and connected to the first board. Each of the plurality of semiconductor memory chips includes only a plurality of first terminals for one channel configured of a predetermined number of terminals. The plurality of first terminals serve as terminals capable of transferring data signals or timing signals. The plurality of connection terminals include only a plurality of second terminals for one channel configured of the predetermined number of terminals. The plurality of second terminals serve as terminals capable of transferring the data signals or the timing signals.

Hereinafter, a memory system and a semiconductor storage device of the embodiment will be described with reference to the drawings. In the following description, components having the same or similar functions are denoted by the same reference signs. Duplicate descriptions of the components may be omitted. In the present application, “parallel”, “orthogonal”, or “the same” may include “substantially parallel”, “substantially orthogonal”, or “substantially the same”, respectively. In the present application, the “connection” is not limited to mechanical connection, and may include electrical connection. That is, the “connection” is not limited to direct connection to an object, and may include connection to an object with another member interposed therebetween.

In the present application, a +X direction, a −X direction, a +Y direction, a −Y direction, a +Z direction, and a −Z direction are defined as follows. The +X direction, the −X direction, the +Y direction, and the −Y direction are directions parallel to a first surface 11a of a board 11 (see FIG. 1), which will be described later. The +X direction is a direction from a controller 12 to a NAND package 14, which will be described later (see FIG. 1). The −X direction is an opposite direction to the +X direction. When the +X direction and the −X direction are not distinguished from each other, the +X direction and the −X direction are simply referred to as the “X direction”. The +Y direction and the −Y direction are directions that intersect (for example, are perpendicular to) the X direction. The +Y direction is a direction from a third end 14e3 to a fourth end 14e4 of the NAND package 14 to be described later (see FIG. 1). The −Y direction is a direction opposite to the +Y direction. When the +Y direction and the −Y direction are not distinguished from each other, the +Y direction and the −Y direction are simply referred to as a “Y direction”.

The +Z direction and the −Z direction are directions that intersect (for example, are perpendicular to) the X direction and the Y direction. The +Z direction and the −Z direction are thickness directions of the board 11. The +Z direction is a direction from a second surface 11b to the first surface 11a of the board 11 (see FIG. 1). The −Z direction is a direction opposite to the +Z direction. When the +Z direction and the −Z direction are not distinguished from each other, the +Z direction and the −Z direction are simply referred to as the “Z direction”. The X direction is an example of a “first direction”. Hereinafter, on the side in the +Z direction may be referred to as “up” and on the side in the −Z direction may be referred to as “down”. However, these expressions are for convenience of description and do not define a direction of gravity.

### First Embodiment

### A1. Overall Configuration of Memory System

A memory system 1 of the first embodiment will be described with reference to FIGS. 1 to 6. The memory system 1 is, for example, a storage device such as a solid state drive (SSD). The memory system 1 is connected to a host device. The memory system 1 is used as a storage device for the host device. The host device may be a personal computer, a mobile device, a video recorder, or an in-vehicle device, but is not limited thereto.

FIG. 1 is a perspective view showing the memory system 1. The memory system 1 includes, for example, the board 11, the controller 12, a dynamic random access memory (DRAM) 13, and a plurality of NAND flash memories 14 (hereinafter, referred to as “NAND package 14” for convenience).

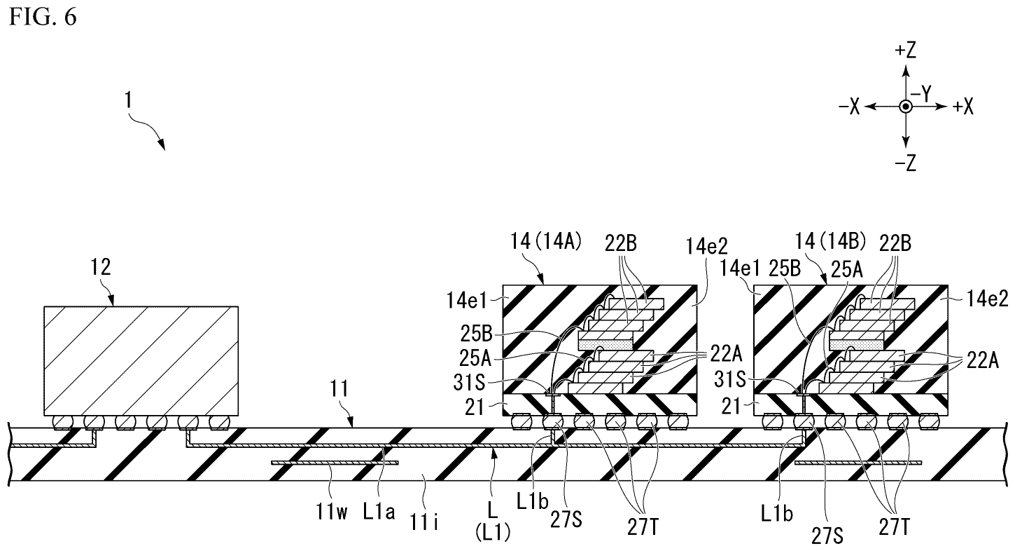

The board 11 is a plate member along the X direction and the Y direction. The board 11 is a printed circuit board. The board 11 includes an insulating board 11i and a wiring pattern 11w. The wiring pattern 11w is provided on the insulating board 11i (see FIG. 6). The insulating board 11i is an insulating hard member formed of an insulating material such as glass epoxy resin or polyimide. The wiring pattern 11w is a conductive portion provided on a surface of the insulating board 11i or inside the insulating board 11i. The board 11 includes the first surface 11a and the second surface 11b. The second surface 11b is located on the side opposite to the first surface 11a. The first surface 11a is a surface facing the +Z direction. The second surface 11b is a surface facing the −Z direction. Each of the first surface 11a and the second surface 11b extends in the X direction and the Y direction. The board 11 is an example of a “first board”.

An end of the board 11 on the side in the −X direction includes a connector 11c. The connector 11c is a connection portion that can be connected to a connector of the host device. The connector 11c includes a plurality of metal terminals that can be connected to the connector of the host device.

The controller 12 is a component that controls the entire memory system 1. The controller 12 is an example of a “control circuit”. The controller 12 is a semiconductor package. The semiconductor package includes a system on a chip (SoC). In the system on a chip, for example, a host interface circuit for the host device, a control circuit that controls the DRAM 13, a control circuit that controls a plurality of NAND packages 14, and the like are integrated in a single semiconductor chip. The controller 12 is mounted, for example, on the first surface 11a of the board 11.

The DRAM 13 is a semiconductor package including a volatile semiconductor memory chip. The DRAM 13 is a data buffer. In the data buffer, write target data received from the host device, read target data read from the NAND package 14, or the like is to be temporarily stored. The DRAM 13 is mounted, for example, on the second surface 11b of the board 11. Note that, the DRAM 13 may be provided in the controller 12 instead of being provided in the board 11.

The NAND package 14 is a semiconductor package including a non-volatile semiconductor memory chip. The plurality of NAND packages 14 are mounted, for example, separately on the first surface 11a and the second surface 11b of the board 11. For example, the plurality of NAND packages 14 include four NAND packages 14 (first to fourth NAND packages 14A to 14D) mounted on the first surface 11a of the board 11. The first to fourth NAND packages 14A to 14D are disposed side by side, for example, in the X direction. Each NAND package 14 is an example of a “semiconductor storage device”.

In the present embodiment, the NAND package 14 has a rectangular shape that is elongated in the Y direction when viewed from the Z direction. The NAND package 14 includes, for example, a first end 14e1, a second end 14e2, a third end 14e3, and a fourth end 14e4. The first end 14e1 and the second end 14e2 are a pair of ends separated in a short side direction (X direction) of the NAND package 14. The third end 14e3 and the fourth end 14e4 are a pair of ends separated in a longitudinal direction (Y direction) of the NAND package 14.

In the present embodiment, a width W1 of the NAND package 14 in the Y direction is greater than the width W2 of the NAND package 14 in the X direction. For example, the width W1 of the NAND package 14 in the Y direction is 1.5 times or more the width W2 of the NAND package 14 in the X direction. In one example of the NAND package 14, the width W1 is 10 mm and the width W2 is 5 mm. In another example of the NAND package 14, the width W1 is 15 mm and the width W2 is 10 mm. The NAND package 14 includes a plurality of connection terminals 27 as will be described later (see FIG. 5). A center-to-center distance PT of the plurality of connection terminals 27 is, for example, 0.5 mm to 0.8 mm.

### A2. Types of Signals to be Transmitted and Received

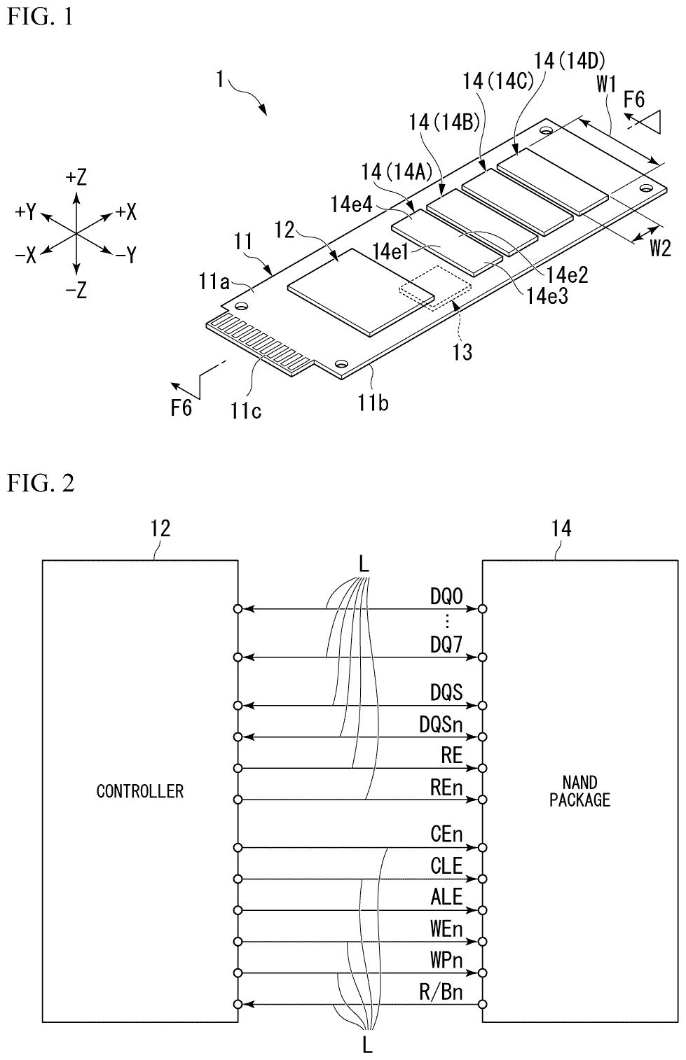

FIG. 2 is a diagram showing a connection relationship between the controller 12 and the NAND package 14. For convenience of description, only one NAND package 14 is shown in FIG. 2. Signals to be transmitted and received between the controller 12 and the NAND package 14 include, for example, 8-bit data signals DQ (DQ0 to DQ7), a data strobe signal DQS/DQSn, a read enable signal RE/REn, a chip enable signal CEn, a command latch enable signal CLE, an address latch enable signal ALE, a write enable signal WEn, a write protect signal WPn, and a ready/busy signal R/Bn. Transmission, reception, and transmission and reception of these signals are performed via individual transmission lines L provided between the controller 12 and the NAND package 14.

The data signals DQ (DQ0 to DQ7) are, for example, signals indicating content of data that is transferred between the controller 12 and the NAND package 14. In the present embodiment, the data signals DQ (DQ0 to DQ7) include a signal indicating content of write target data (write data) in the NAND package 14, a signal indicating content of read target data (read data) from the NAND package 14, a signal indicating various commands, and a signal indicating an address of a data write destination or data read destination, or the like. The data signals DQ (DQ0 to DQ7) are transmitted and received, for example, in units of 8 bits, via eight independent transmission lines L. Note that, the data signal DQ may be transmitted and received via a plurality of transmission lines L corresponding to another number of bits (for example, 16 bits) in units of the other number of bits.

The data strobe signal DQS/DQSn is a strobe signal that is used to latch the data signal DQ or output the data signal DQ. The data strobe signal DQS/DQSn includes, for example, a toggle pattern signal (hereinafter, referred to as a “toggle signal”). The data strobe signal DQS/DQSn includes a data strobe signal DQS and a data strobe signal DQSn. The data strobe signal DQS and the data strobe signal DQSn are a pair of signals having a complementary relationship. For example, the data strobe signal DQS is a positive logic data strobe signal. On the other hand, the data strobe signal DQSn is a negative logic data strobe signal having a logical inversion relationship with respect to the data strobe signal DQS.

Here, examples of each of the data strobe signal DQS and the data strobe signal DQSn include a strobe signal for write data reception, a strobe signal for read data transmission, and a strobe signal for read data reception. The strobe signal for write data reception is a strobe signal that is output from the controller 12 to the NAND package 14 together with write data in a write data write operation, and is used to specify a timing when the write data is latched in the NAND package 14. The strobe signal for read data transmission is a strobe signal that is output from the controller 12 to the NAND package 14 in synchronization with the read enable signal RE/REn (or a read enable signal RE) to be described later and is used in the NAND package 14 in order to receive an edge thereof and output read data from the NAND package 14 to the controller 12 in a read data read operation. The strobe signal for read data reception is a strobe signal that is generated in the NAND package 14, output from the NAND package 14 to the controller 12 together with the read data, and used to specify a timing when read data is latched in the controller 12 in the read data read operation. Each of the data strobe signal DQS and the data strobe signal DQSn is an example of a “timing signal”.

The read enable signal RE/REn is a signal that enables data to be read from the NAND package 14. The read enable signal RE/REn may include, for example, a toggle signal. The read enable signal RE/REn includes a read enable signal RE and a read enable signal REn. The read enable signal RE and the read enable signal REn are a pair of signals that have a complementary relationship. For example, the read enable signal RE is a positive logic read enable signal. On the other hand, the read enable signal REn is a negative logic data strobe signal having a logical inversion relationship with the read enable signal RE. Each of the read enable signal RE and the read enable signal REn is an example of a “timing signal”.

The chip enable signal CEn is a signal that enables the selection of the NAND package 14 that are access targets from among the plurality of NAND packages 14, and is asserted when the NAND package 14 is selected. The command latch enable signal CLE is a signal that enables a command output from the controller 12 to the NAND package 14 to be latched in a command register in the NAND package 14. The address latch enable signal ALE is a signal that enables an address output from the controller 12 to the NAND package 14 to be latched in an address register in the NAND package 14. Each of the chip enable signal CEn, the command latch enable signal CLE, and the address latch enable signal ALE is an example of a “state notification signal”.

The write enable signal WEn is a signal that enables data (for example, a command or an address) to be passed to the NAND package 14. The write protect signal WPn is a signal that is asserted when writing and erasing are prohibited. The ready/busy signal R/Bn is a signal that distinguishably indicates whether the NAND package 14 is in a ready state or a busy state. The “ready state” is a state in which the NAND package 14 can accept commands from the controller 12. The “busy state” is a state in which the NAND package 14 cannot accept commands from the controller 12. Each of the write enable signal WEn, the write protect signal WPn, and the ready/busy signal R/Bn is an example of a “state notification signal”.

### A3. Structure of the NAND Package

Next, a structure of the NAND package 14 will be described.

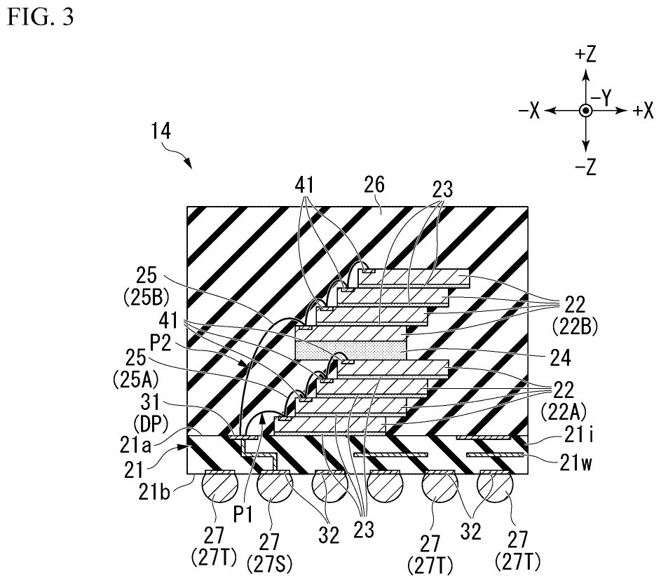

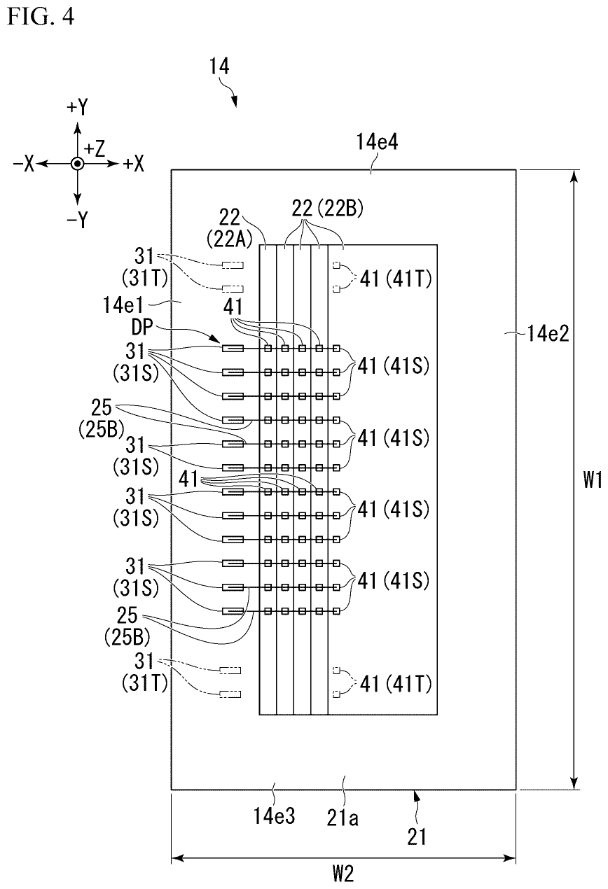

FIG. 3 is a cross-sectional view showing the NAND package 14. Hereinafter, the NAND package 14 mounted on the first surface 11a of the board 11 will be described as a representative example of the NAND package 14. The NAND package 14 includes, for example, a board 21, a plurality of semiconductor memory chips 22, a plurality of adhesive films 23, an adhesive film 24, a plurality of bonding wires 25, a sealing member 26, and a plurality of connection terminals 27. Hereinafter, the board 21 included in the NAND package 14 will be referred to as a “package board 21” to distinguish the board 21 from the above-described board 11.

### (Package Board)

The package board 21 is a plate member along the X direction and the Y direction. The package board 21 is a printed circuit board. The board 21 includes an insulating board 21i and a wiring pattern 21w. The insulating board 21i is an insulating hard member formed of an insulating material such as glass epoxy resin or polyimide. The wiring pattern 21w is a conductive part provided on a surface of the insulating board 21i or inside the insulating board 21i. A shape of the package board 21 is a rectangle shape that is the same as an outer shape of the NAND package 14 when viewed from the Z direction. The package board 21 is an example of a “second board”.

The package board 21 includes a first surface 21a and a second surface 21b. The second surface 21b is located on the side opposite to the first surface 21a. The first surface 21a is a surface facing the side opposite to the board 11 (a surface facing the +Z direction). The first surface 21a includes a plurality of pads 31. The bonding wires 25, which will be described later, are connected to the plurality of pads 31. The second surface 21b, on the other hand, is a surface facing the board 11 (for example, a surface facing the −Z direction). The second surface 21b includes a plurality of pads 32. The connection terminals 27, which will be described later, are connected to the plurality of pads 32.

### (Semiconductor Memory Chip)

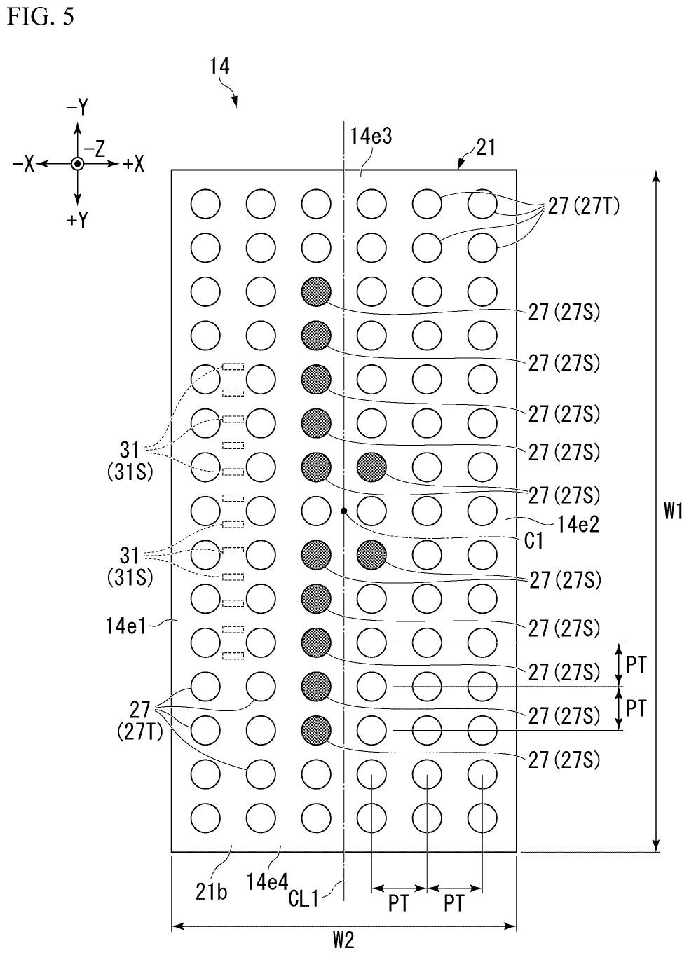

The semiconductor memory chip 22 is a semiconductor component capable of storing data. The semiconductor memory chip 22 is, for example, a non-volatile semiconductor memory chip. The semiconductor memory chip 22 is, for example, a NAND-type flash memory chip. The semiconductor memory chip 22 includes a plurality of memory cell transistors, and a peripheral circuit. The peripheral circuit is configured to cause the plurality of memory cell transistors to function as memory elements. The semiconductor memory chip 22 is in the form of a plate extending along the X direction and the Y direction. The semiconductor memory chip 22 has a rectangular shape that is elongated in the Y direction when viewed from the Z direction (see FIG. 4). The plurality of semiconductor memory chips 22 are disposed between the first surface 21a of the package board 21 and the sealing member 26, which will be described later.

In the present embodiment, the plurality of semiconductor memory chips 22 include a plurality of (for example, four) first semiconductor memory chips 22A and a plurality of (for example, four) second semiconductor memory chips 22B.

The plurality of first semiconductor memory chips 22A are stacked in the Z direction with adhesive film 23 interposed therebetween. The adhesive film 23 is, for example, a die attach film. The plurality of first semiconductor memory chips 22A are stacked on the first surface 21a of the package board 21. Among the plurality of first semiconductor memory chips 22A, as the first semiconductor memory chip 22A is farther away from the package board 21, the first semiconductor memory chip 22A is disposed to be significantly displaced to the side in the +X direction. Each of the first semiconductor memory chips 22A includes a plurality of pads 41 in an area that does not overlap other first semiconductor memory chips 22A when viewed from the Z direction. The pads 41 are pads to which bonding wires 25, which will be described later, are connected.

In the present embodiment, the adhesive film 24 is provided on the topmost first semiconductor memory chip 22A among the plurality of first semiconductor memory chips 22A. The adhesive film 24 is, for example, a thick die attach film. A thickness of the adhesive film 24 in the Z direction is greater than the thickness of the adhesive film 23 in the Z direction. The adhesive film 24 covers the pads 41 of the topmost first semiconductor memory chip 22A, and a portion of the bonding wires 25 connected to the pads 41 of the topmost first semiconductor memory chip 22A. For example, the portion of the bonding wires 25 extends through the inside of the adhesive film 24.

The plurality of second semiconductor memory chips 22B are located on the opposite side of the package board 21 with respect to the plurality of first semiconductor memory chips 22A. The plurality of second semiconductor memory chips 22B are stacked in the Z direction with the adhesive film 23 interposed therebetween. Among the plurality of second semiconductor memory chips 22B, as the second semiconductor memory chip 22B is farther away from the package board 21, the second semiconductor memory chip 22B is disposed to be significantly displaced to the side in the +X direction. The plurality of second semiconductor memory chips 22B are stacked on the plurality of first semiconductor memory chips 22A via the adhesive film 24. In the present embodiment, the bottommost second semiconductor memory chip 22B among the plurality of second semiconductor memory chips 22B is disposed to be displaced to the side in the −X direction with respect to the topmost first semiconductor memory chip 22A described above. Each of the second semiconductor memory chips 22B includes the plurality of pads 41 in an area that does not overlap another second semiconductor memory chip 22B when viewed from the Z direction. The pads 41 are pads to which the bonding wires 25 to be described later are connected.

### (Bonding Wires)

The bonding wires 25 are electrical connection portions that connect the package board 21 to the semiconductor memory chip 22. In the present embodiment, the plurality of bonding wires 25 include a plurality of first bonding wires 25A (only one first bonding wire is shown in FIG. 3) and a plurality of second bonding wires 25B (only one second bonding wire is shown in FIG. 3).

Each of the first bonding wires 25A electrically connects the pads 41 of the plurality of first semiconductor memory chips 22A to the pad 31 of the package board 21. Each of the first bonding wires 25A is provided at ends of the plurality of first semiconductor memory chips 22A on the side in the −X direction. In the present embodiment, one end of each of the first bonding wires 25A is bonded to the pad 31 of the package board 21. Each of the first bonding wires 25A extends via the pads 41 of the plurality of first semiconductor memory chips 22A in order from the pad 31 of the package board 21. Each of the first bonding wires 25A electrically connects the pads 41 of the plurality of first semiconductor memory chips 22A in series.

Each of the second bonding wires 25B electrically connects the pads 41 of the plurality of second semiconductor memory chips 22B to the pad 31 of the package board 21. Each of the second bonding wires 25B is provided at an end of the second semiconductor memory chips 22B on the side in the −X direction. One end of each of the second bonding wires 25B is bonded to the pad 31 of the package board 21. Each of the second bonding wires 25B extends via the pads 41 of the second semiconductor memory chips 22B in order from the pad 31 of the package board 21. Each of the second bonding wires 25B electrically connects the pads 41 of the second semiconductor memory chips 22B in series.

### (Sealing Member)

The sealing member 26 is an insulating part that protects the plurality of semiconductor memory chips 22 and the plurality of bonding wires 25. The sealing member 26 is, for example, a molded resin. The sealing member 26 is provided on the first surface 21a of the package board 21. The sealing member 26 covers the first surface 21a of the package board 21 when viewed from the Z direction. The sealing member 26 covers the plurality of semiconductor memory chips 22 and the plurality of bonding wires 25 from the side opposite to the first surface 21a of the package board 21. For example, a shape of the sealing member 26 is a rectangular shape that is the same as the outer shape of the NAND package 14, when viewed from the Z direction.

### (Connection Terminal)

The connection terminals 27 are electrical connection portions that connect the NAND package 14 to the board 11. The plurality of connection terminals 27 are provided on the second surface 21b of the board 21. The plurality of connection terminals 27 are exposed to the outside of the NAND package 14. The plurality of connection terminals 27 are arranged in a grid pattern along the X direction and the Y direction, for example (see FIG. 5). In the present embodiment, the plurality of connection terminals 27 are a ball grid array (BGA) type of solder joints. However, the connection terminals 27 are not limited to the above-described example. The connection terminals 27 may be pads connected to the outside via conductive paste, may be terminals such as lead frames or pins, or may be terminals connected to the outside in other aspects.

### A4. Terminals of Semiconductor Memory Chip

Next, the pads 41 of the semiconductor memory chip 22 will be described.

FIG. 4 is a plan view showing the NAND package 14. For convenience of description, the sealing member 26 is omitted in FIG. 4. Each semiconductor memory chip 22 includes the plurality of pads 41 to which the plurality of bonding wires 25 are connected in one-to-one correspondence.

In the present embodiment, the plurality of pads 41 of each semiconductor memory chip 22 include only a plurality of pads 41S for one channel configured of a predetermined number of (for example, 12) terminals. The terminals serve as terminals capable of transferring data signals or timing signals. In the present embodiment, the 12 pads 41S are an example of a “plurality of first terminals”.

In the present embodiment, the 12 pads 41S which are the predetermined number of terminals (terminals for one channel) include, for example, eight pads 41S capable of transferring the 8-bit data signal DQ, one pad 41S capable of transferring the data strobe signal DQS, one pad 41S capable of transferring the data strobe signal DQSn, one pad 41S capable of transferring the read enable signal RE, and one pad 41S capable of transferring the read enable signal REn. The 12 pads 41S are disposed side by side, for example, in the Y direction.

In the present application, “each semiconductor memory chip includes only a plurality of terminals for one channel configured of a predetermined number of terminals, as a plurality of terminals capable of transferring data signals or timing signals” means that each semiconductor memory chip includes only the predetermined number of pads 41S (terminals for one channel) as the terminals capable of transferring data signals or timing signals, and may include a case in which there are other terminals that are used for purposes other than transferring the data signals and timing signals. For example, the plurality of pads 41 of each semiconductor memory chip 22 include a plurality of pads 41T. The pads 41T serve as terminals other than the predetermined number of pads 41S. The plurality of pads 41T are terminals for power supply, terminals for ground connection, or the like.

In the present embodiment, the plurality of pads 31 provided on the first surface 21a of the package board 21 include a plurality of pads 31S and a plurality of pads 31T. The plurality of pads 31S are the predetermined number of (for example, 12) pads. The plurality of pads 31S and the plurality of pads 41S of each semiconductor memory chip 22 are electrically connected in a one-to-one relationship via the plurality of bonding wires 25. The term “one-to-one relationship” here means that, in terms of one semiconductor memory chip 22, the plurality of pads 31S of the package board 21 and the plurality of pads 41S of the one semiconductor memory chip 22 are electrically connected in a one-to-one relationship. As described above, in the present embodiment, each of the first bonding wires 25A electrically connects the pads 41 of the plurality of first semiconductor memory chips 22A in series. Further, each of the second bonding wires 25B electrically connects the pads 41 of the plurality of second semiconductor memory chips 22B in series. To this end, in the entire NAND package 14, each pad 31S and the eight pads 41S separately present in the eight semiconductor memory chips 22 are electrically connected in a one-to-eight relationship.

Similarly, the plurality of pads 31T and the plurality of pads 41T of each semiconductor memory chip 22 are electrically connected in a one-to-one relationship via the plurality of bonding wires 25. The term “one-to-one relationship” here means that, in terms of one semiconductor memory chip 22, the plurality of pads 31T of the package board 21 and the plurality of pads 41T of the semiconductor memory chip 22 are electrically connected in a one-to-one relationship. In the entire NAND package 14, each pad 31T and the eight pads 41T separately present in the eight semiconductor memory chips 22 are electrically connected in a one-to-eight relationship.

### A5. Connection Terminals of NAND Package

Next, connection terminals 27 of the NAND package 14 will be described.

FIG. 5 is a bottom view showing the NAND package 14. As described above, the plurality of connection terminals 27 are arranged in a grid pattern along the X direction and the Y direction, for example.

In the present embodiment, the plurality of connection terminals 27 of the NAND package 14 include only a plurality of connection terminals 27S for one channel configured of the above-described predetermined number of (for example, 12) terminals. The plurality of connection terminals 27S serve as terminals capable of transferring data signals or timing signals. In the present embodiment, the 12 connection terminals 27S are examples of “a plurality of second terminals”.

In the present embodiment, the 12 connection terminals 27S which are the predetermined number of terminals (terminals for one channel) include, for example, eight connection terminals 27S capable of transferring 8-bit data signals DQ, one connection terminal 27S capable of transferring the data strobe signal DQS, one connection terminal 27S capable of transferring the data strobe signal DQSn, one connection terminal 27S capable of transferring the read enable signal RE, and one connection terminal 27S capable of transferring the read enable signal REn.

Here, a center line CL1 passing in the Y direction through a center C1 of the package board 21 in the X direction (a center of the NAND package 14 in the X direction) when viewed from the Z direction is defined for the sake of description. In the present embodiment, the 12 connection terminals 27S are disposed asymmetrically on both sides of the center line CL1 in the X direction (that is, the side in the +X direction and the side in the −X direction). In the example shown in FIG. 5, the 12 connection terminals 27S include a first number of (for example, 10) connection terminals 27S and a second number of (for example, two) connection terminals 27S. The first number of the connection terminals 27S are disposed on the side closer to the controller 12 (on the side in the −X direction) with respect to the center C1 of the package board 21 in the X direction. The second number of the second connection terminals 27S are disposed on the side farther from the controller 12 (on the side in the +X direction). The first number is larger than the second number.

In the present application, “the plurality of connection terminals include only a plurality of terminals for one channel configured of a predetermined number of terminals, and the plurality of terminals serve as terminals capable of transferring data signals or timing signals” means that the plurality of connection terminals include only the predetermined number of terminals (terminals for one channel) as terminals capable of transferring data signals or timing signals, and may include a case in which there are other terminals that are used for purposes other than transferring the data signals and the timing signals. For example, the plurality of connection terminals 27 include a plurality of connection terminals 27T. The connection terminals 27T serve as terminals other than the predetermined number of connection terminals 27S. The plurality of connection terminals 27T are, for example, terminals capable of transferring control signals (for example, a state notification signal) such as the chip enable signal CEn, the command latch enable signal CLE, the address latch enable signal ALE, the write enable signal WEn, the write protect signal WPn, or the ready/busy signal R/Bn, terminals for power supply, or terminals for ground connection.

### A6. Branching Portion of NAND Package

Next, referring back to FIG. 3, a branching portion DP of the NAND package 14 will be described. In the present embodiment, the NAND package 14 includes the branching portion DP, a path P1, and a path P2. The path P1 is an example of a “first path”. The path P2 is an example of a “second path”. The path P1 electrically connects the plurality of connection terminals 27S (the predetermined number of connection terminals 27S) included in the connection terminal 27 to the plurality of first bonding wires 25A. The path P2 electrically connects the plurality of connection terminals 27S (the predetermined number of connection terminals 27S) included in the connection terminal 27 to the plurality of second bonding wires 25B in electrical parallel to the path P1. At the branching portion DP, a path of the NAND package 14 is branched into the path P1 and the path P2.

In the present embodiment, the branching portion DP is provided on the package board 21. The branching portion DP includes, for example, the above-described predetermined number of (for example, 12) pads 31S among the plurality of pads 31 provided on the package board 21. Each pad 31S is electrically connected to one connection terminal 27S included in the plurality of connection terminals 27S. Further, the first bonding wire 25A and the second bonding wire 25B are electrically connected to each pad 31 in parallel. Accordingly, each pad 31 electrically connects one connection terminal 27S to one pad 41S of each first semiconductor memory chip 22A, and also electrically connects the one connection terminal 27S to one pad 41S of each second semiconductor memory chip 22B.

### A7. Configuration of Board of Memory System

Next, the board 11 of the memory system 1 will be described.

FIG. 6 is a cross-sectional view showing the memory system 1 shown in FIG. 1 taken along line F6-F6. In the present embodiment, the plurality of transmission lines L of the board 11 include a plurality of transmission lines L1 (only one is shown in FIG. 6) through which the data signal DQ (DQ0 to DQ7), the data strobe signal DQS, the data strobe signal DQSn, the read enable signal RE, or the read enable signal REn are transferred. The transmission line L1 includes, for example, a wiring body L1a, and one or more connection portions L1b. The connection portions L1b are branched from the wiring body L1a. The connection portion L1b is a wiring portion that connects the wiring body L1a to the NAND package 14. The connection portion L1b is provided so that only one connection portion L1b is connected to each NAND package 14 for each transmission line L1.

### A8. Advantages

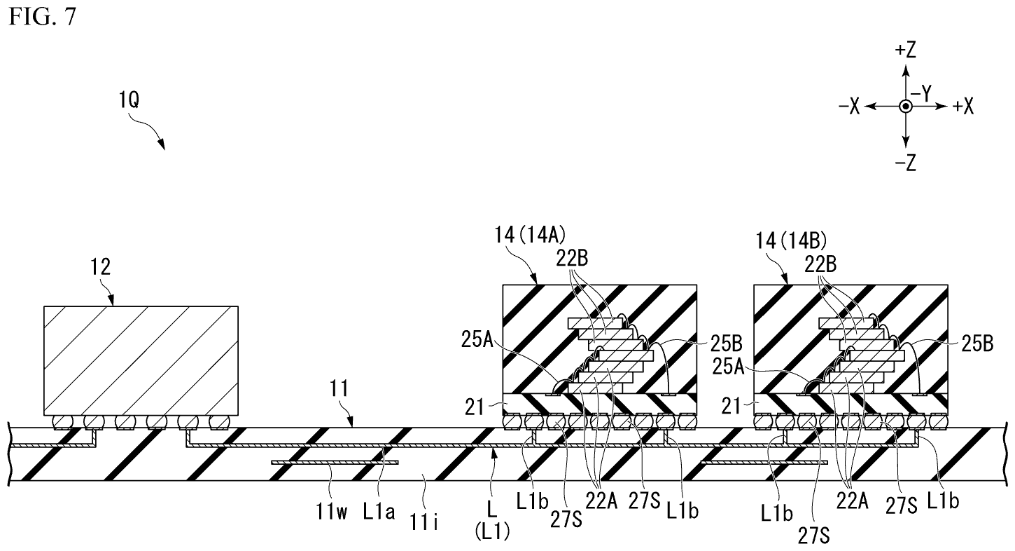

FIG. 7 is a cross-sectional view showing a memory system 1Q of a comparative example. As a comparative example, a configuration in which each NAND package 14 includes connection terminals 27S for two channels. The two channels serve as terminals capable of transferring data signals or timing signals is considered herein. In other words, the NAND package 14 of the comparative example includes two connection terminals 27S corresponding to the same signal. The transmission line L1 includes two connection portions L1b that are connected to the two connection terminals 27S for each NAND package 14.

In the configuration of this comparative example, the number of branching portions (connection portions L1b) branched from the wiring body L1a is large. With this configuration, signal quality of signals transferred using the transmission line L1 may be degraded due to an influence of signal reflection by the branching portion. This influence becomes easily noticeable as a speed of the memory system 1 increases. Further, when the connection terminals 27S for two channels are provided in the NAND package 14, it becomes difficult to downsize the NAND package 14.

On the other hand, in the present embodiment, the NAND package 14 includes the plurality of semiconductor memory chips 22 and the plurality of connection terminals 27. Each of the plurality of semiconductor memory chips 22 includes only the plurality of pads 41S for one channel configured of a predetermined number of terminals, as the plurality of terminals capable of transferring data signals or timing signals. The plurality of connection terminals 27 include the plurality of connection terminals 27S for one channel configured of the predetermined number of terminals, as the plurality of terminals capable of transferring data signals or timing signals. With this configuration, the number of branching portions (connection portions L1b) branched from the wiring body L1a can be reduced compared to the comparative example. Therefore, an influence of signal reflection by the branching portions is reduced, and the signal quality of the signal transferred using the transmission line L1 is difficult to degrade. Further, when the connection terminals 27S for one channel are provided in the NAND package 14, it is easier to downsize the NAND package 14 compared to the comparative example.

In the present embodiment, the plurality of semiconductor memory chips 22 include a plurality of first semiconductor memory chips 22A and a plurality of second semiconductor memory chips 22B. The plurality of bonding wires 25 include the plurality of first bonding wires 25A and the plurality of second bonding wires 25B. The plurality of first bonding wires 25A are connected to the plurality of pads 41S of the plurality of first semiconductor memory chips 22A. The plurality of second bonding wires 25B are connected to the plurality of pads 41S of the plurality of second semiconductor memory chips 22B. The NAND package 14 includes the branching portion DP, a path P1, and a path P2. The path P1 is an example of a “first path”. The path P2 is an example of a “second path”. The path P1 electrically connects the plurality of connection terminals 27S to the plurality of first bonding wires 25A. The path P2 electrically connects the plurality of connection terminals 27S to the plurality of second bonding wires 25B in electrical parallel with the plurality of first bonding wires 25A. At the branching portion DP, a path of the NAND package 14 is branched into the path P1 and the path P2. With this configuration, it is possible to realize a connection relationship for two channels within the NAND package 14, and it is easy for electrical characteristics (for example, high speed) of the NAND package 14 to be improved.

In the present embodiment, the package board 21 includes the branching portion DP. With this configuration, it is possible to realize the branching portion DP using the package board 21. This makes it easy to downsize the NAND package 14 compared to a case in which a special additional component is provided in the NAND package 14.

In the present embodiment, the branching portion DP includes the plurality of pads 31S provided on the first surface 21a of the package board 21. The plurality of first bonding wires 25A are connected to the plurality of pads 31S. The plurality of second bonding wires 25B are connected to the plurality of pads 31S electrically in parallel with the plurality of first bonding wires 25A. With this configuration, it is possible to realize the branching portion DP using the pad 31 of the package board 21. This makes it easy to downsize the NAND package 14.

In the present embodiment, the plurality of connection terminals 27S include a first number of connection terminals 27S and a second number of connection terminals 27S. The first number of the connection terminals 27S are disposed on the side closer to the controller 12. The second number of the connection terminals 27S are disposed on the side farther from the controller 12 with respect to the center C1 of the package board 21 in the X direction. The first number is larger than the second number. According to such a configuration, it is possible to shorten a distance between the connection terminal 27S and the controller 12. When it is possible to shorten the distance between the connection terminal 27S and the controller 12, it becomes easy to increase the speed of the memory system 1.

### A9. Modified Examples

Hereinafter, several modified examples will be described. Note that, in each modified example, a configuration other than that to be described below is the same as that of the first embodiment described above.

### First Modified Example

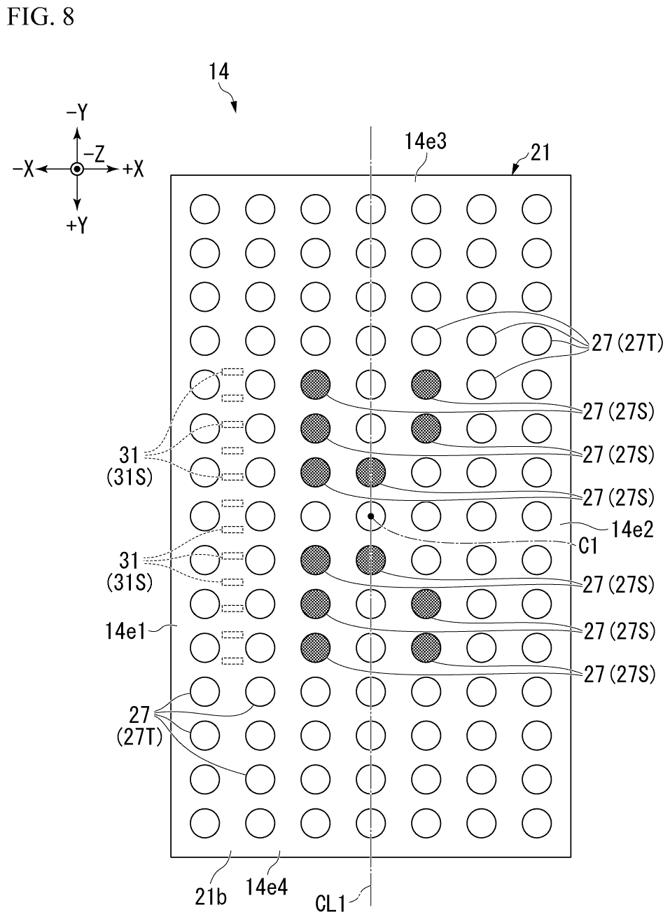

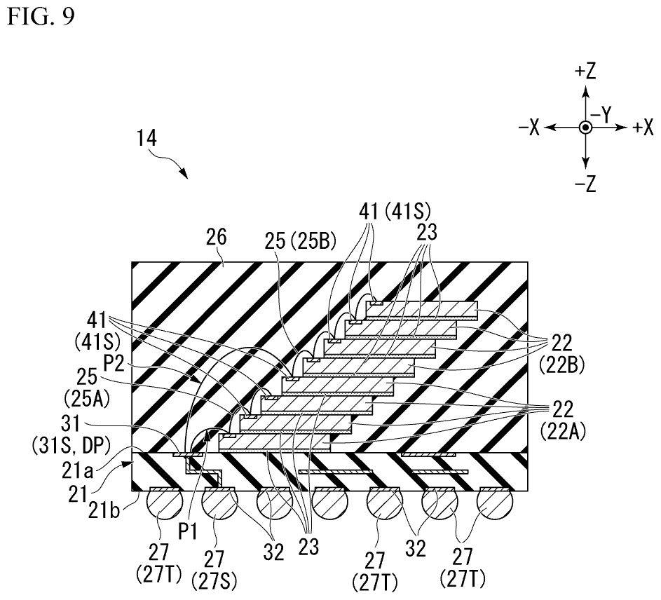

FIG. 8 is a bottom view showing the NAND package 14 according to a first modified example. A plurality of connection terminals 27 of the first modified example include only a plurality of connection terminals 27S for one channel configured of the predetermined number of (for example, 12) terminals. The plurality of connection terminals 27S serve as terminals capable of transferring data signals or timing signals, as in the first embodiment described above.

In the present modified example, the 12 connection terminals 27S are disposed asymmetrically on both the sides of the center line CL1 in the X direction (that is, the side in the +X direction and the side in the −X direction). In the present modified example, the 12 connection terminals 27S include a first number of (for example, six) connection terminals 27S, a second number of (for example, four) connection terminals 27S, and a third number of (for example, two) connection terminals 27S. The first number of the connection terminals 27S are disposed on the side closer to the controller 12 (on the side in the −X direction) with respect to the center C1 in the X direction of the package board 21. The second number of the connection terminals 27S are disposed on the side farther from the controller 12 (on the side in the +X direction). The third number of the connection terminals 27S are connection terminals 27S that overlap the center line CL1 that passes through the center C1 in the X direction of the package board 21 and extends in the Y direction when viewed from the Z direction. The first number is larger than the second number. Note that, the present modified example may be applied in combination with the second embodiment to be described later. With such a configuration, it is possible to improve electrical characteristics of the memory system 1.

### Second Modified Example

FIG. 9 is a cross-sectional view showing a NAND package 14 according to a second modified example. In the second modified example, the second semiconductor memory chips 22B are stacked in the Z direction with the adhesive film 23 interposed therebetween. Among the plurality of second semiconductor memory chips 22B, as the second semiconductor memory chip 22B is farther away from the package board 21, the second semiconductor memory chip 22B is disposed to be significantly displaced to the side in the +X direction. The plurality of second semiconductor memory chips 22B are stacked on the plurality of first semiconductor memory chips 22A via the adhesive films 23. In the present modified example, the bottommost second semiconductor memory chip 22B among the plurality of second semiconductor memory chips 22B is disposed to be displaced to the side in the +X direction with respect to the topmost first semiconductor memory chip 22A.

In the present modified example, the plurality of first bonding wires 25A are connected to the plurality of first semiconductor memory chips 22A. The plurality of second bonding wires 25B are connected to the plurality of second semiconductor memory chips 22B in electrical parallel with the plurality of first bonding wires 25A. With such a configuration, it is also possible to improve the electrical characteristics of the memory system 1.

### Third Modified Example

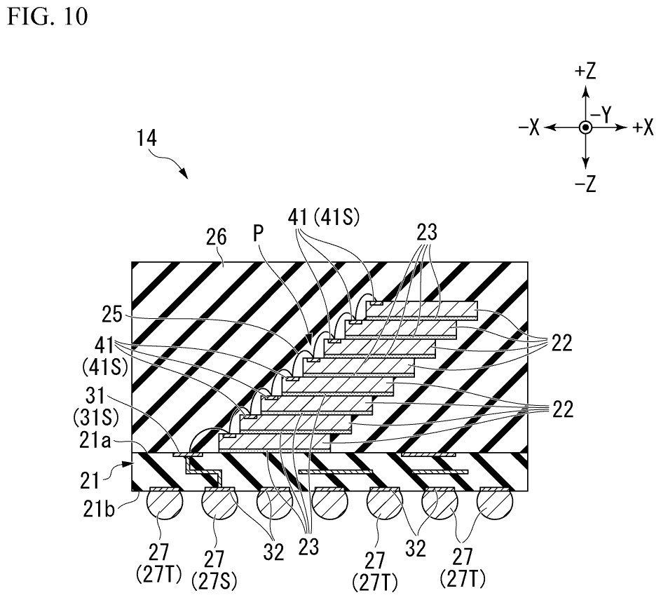

FIG. 10 is a cross-sectional view showing a NAND package 14 according to a third modified example. In the third modified example, all (for example, eight) semiconductor memory chips 22 included in one NAND package 14 are stacked in the Z direction with adhesive films 23 interposed therebetween. Among all the semiconductor memory chips 22, as the semiconductor memory chip 22 is farther away from the package board 21, the semiconductor memory chip 22 is disposed to be significantly displaced to the side in the +X direction. In the present modified example, each bonding wire 25 is provided at the end of the plurality of semiconductor memory chips 22 on the side in the −X direction. The bonding wires 25 extend through the pads 41 of the plurality of semiconductor memory chips 22 in order from the pad 31 of the package board 21. The bonding wires 25 electrically connects the pads 41 of all (for example, eight) semiconductor memory chips 22 in series. In the present modified example, the pads 41 electrically connected in parallel may not be present. In the present modified example, a path that electrically connects each pad 31S of the package board 21 to the plurality of pads 41S (for example, eight pads 41S) separately present in the plurality of semiconductor memory chips 22 (for example, eight semiconductor memory chips 22 that are all the semiconductor memory chips 22) may not be divided into the path P1 and path P2 as described above. In the present modified example, one path P that electrically connects the pads 31S to the plurality of pads 41S (for example, eight pads 41S) separately present in the plurality of semiconductor memory chips 22 (for example, eight semiconductor memory chips 22 that are all the semiconductor memory chips 22) is provided in each pad 31S.

### Second Embodiment

Next, a second embodiment will be described. The second embodiment differs from the first embodiment in that a NAND package 14′ including a relay component 60 is provided. Note that, a configuration other than that to be described below is the same as that of the first embodiment described above.

### <B1. Structure of NAND Package>

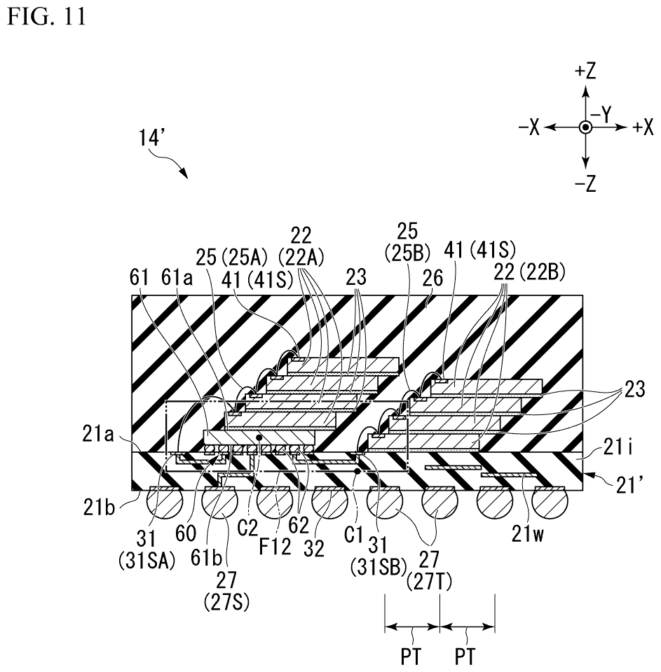

FIG. 11 is a cross-sectional view showing the NAND package 14′ of the second embodiment. The NAND package 14′ includes, for example, a package board 21′, a plurality of (for example, eight) semiconductor memory chips 22, the plurality of adhesive films 23, the plurality of bonding wires 25, the sealing member 26, the plurality of connection terminals 27, and the relay component 60. Note that, the “relay component” may also be called, for example, a “distribution component” or an “interface component”.

### (Relay Component)

The relay component 60 is a semiconductor chip including one or more circuits. The relay component 60 includes, for example, an interface circuit provided between the package board 21 and the plurality of semiconductor memory chips 22. The relay component 60 may include, for example, a control circuit configured to control the plurality of semiconductor memory chips 22. In the present embodiment, the relay component 60 is a package component including a plurality of connection terminals. The relay component 60 includes, for example, a component body 61 and a plurality of connection terminals 62.

The component body 61 includes an interface circuit 60a, which will be described later. The component body 61 has a plate shape. The component body 61 includes a first surface 61a, and a second surface 61b. The second surface 61b is located on the side opposite to the first surface 61a. The first surface 61a is surface directed in the +Z direction. The second surface 61b is surface directed in the −Z direction. The interface circuit 60a (for example, an element included in the interface circuit 60a) is disposed closer to the second surface 61b than to the first surface 61a.

The connection terminals 62 are electrical connection portions that connect the component body 61 to the package board 21. The plurality of connection terminals 62 are provided on the second surface 61b of the component body 61. The plurality of connection terminals 62 are arranged in a grid pattern along the X direction and the Y direction, for example. In the present embodiment, the plurality of connection terminals 62 are a BGA type of solder joints (so-called microbumps). However, the connection terminals 62 are not limited to the above-described example.

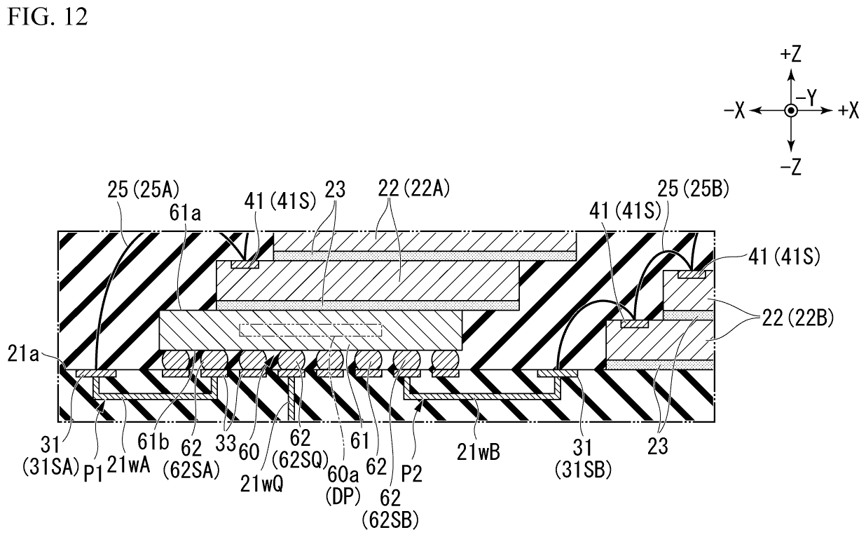

In the present embodiment, the first surface 21a of the package board 21 includes a plurality of pads 33 (see FIG. 12) electrically connected to the relay component 60. The relay component 60 is flip-chip mounted on the first surface 21a of the package board 21. The plurality of connection terminals 62 of the relay component 60 are connected to the plurality of pads 33 of the package board 21.

As shown in FIG. 11, a center C2 in the X direction of the relay component 60 is disposed to be displaced to the side closer to the controller 12 (on the side in the −X direction) with respect to the center C1 in the X direction of the package board 21 (a center in the X direction of the NAND package 14′). For example, the center C2 of the relay component 60 in the X direction is disposed to be displaced by 1 mm or more to the side closer to the controller 12 (on the side in the −X direction) with respect to the center C1 of the package board 21 in the X direction. From another perspective, the center C2 of the relay component 60 in the X direction is disposed to be displaced by a predetermined distance or more to the side closer to the controller 12 (on the side in the −X direction) with respect to the center C1 of the package board 21 in the X direction. The predetermined distance is a distance greater than the center-to-center distance PT of the plurality of connection terminals 27.

### (Semiconductor Memory Chip)

A plurality of (for example, four) first semiconductor memory chips 22A are stacked on the relay component 60 from the side opposite to the package board 21. The plurality of first semiconductor memory chips 22A are stacked on the first surface 61a of the component body 61 of the relay component 60 with the adhesive film 23 interposed therebetween. Among the plurality of first semiconductor memory chips 22A, as the first semiconductor memory chip 22A is farther away from the package board 21, the first semiconductor memory chip 22A is disposed to be significantly displaced to the side in the +X direction.

A plurality of (for example, four) second semiconductor memory chips 22B are disposed at positions away from the relay component 60 when viewed from the Z direction. For example, the plurality of second semiconductor memory chips 22B are disposed on the side in the +X direction with respect to the plurality of first semiconductor memory chips 22A and the relay component 60. The plurality of second semiconductor memory chips 22B are stacked on the first surface 21a of the package board 21 with the adhesive film 23 interposed therebetween. Among the plurality of second semiconductor memory chips 22B, as the second semiconductor memory chip 22B is farther away from the package board 21, the second semiconductor memory chip 22B is disposed to be significantly displaced to the side in the +X direction.

In the present embodiment, a part of the bottommost second semiconductor memory chip 22B is located between the topmost first semiconductor memory chip 22A and the package board 21. In other words, a part of the bottommost second semiconductor memory chip 22B overlaps a part of the topmost first semiconductor memory chip 22A when viewed from the Z direction.

(Pads of Package board)

In the present embodiment, the plurality of pads 31 of the package board 21 include the predetermined number of (for example, 12) pads 31SA and the predetermined number of (for example, 12) pads 31SB.

The predetermined number of pads 31SA are located on the side in the −X direction with respect to the relay component 60. From another perspective, the predetermined number of pads 31SA are located on the side in the −X direction with respect to the plurality of first semiconductor memory chips 22A. The predetermined number of pads 31SA are disposed side by side in the Y direction.

The predetermined number of pads 31SB are located on the side in the +X direction with respect to the relay component 60. From another perspective, the predetermined number of pads 31SA are located on the side in the −X direction with respect to the plurality of second semiconductor memory chips 22B. In the present embodiment, the predetermined number of pads 31SB are located between the relay component 60 and the plurality of second semiconductor memory chips 22B in the X direction. The predetermined number of pads 31SB are disposed side by side in the Y direction.

### (Bonding Wires)

The first bonding wires 25A electrically connect the pads 41S of the plurality of first semiconductor memory chips 22A to the pads 31SA of the package board 21 in one-to-one correspondence. Each of the first bonding wires 25A is disposed on the side in the −X direction with respect to the plurality of first semiconductor memory chips 22A. Each of the first bonding wires 25A is provided at the ends of the first semiconductor memory chips 22A on the side in the −X direction.

In the present embodiment, the first bonding wires 25A are disposed on the side in the −X direction with respect to the relay component 60. One end of each of the first bonding wires 25A is bonded to the pad 31SA of the package board 21. Each of the first bonding wires 25A extends through the pads 41S of the plurality of first semiconductor memory chips 22A in order from the pad 31SA. Each of the first bonding wires 25A is connected to the pad 31SA. Each of the first bonding wires 25A is electrically connected to the relay component 60 through the package board 21.

Each of the second bonding wires 25B electrically connects the pads 41S of the plurality of second semiconductor memory chips 22B to the pads 31SB of the package board 21. Each of the second bonding wires 25B is disposed on the side in the −X direction with respect to the plurality of second semiconductor memory chips 22B. Each of the second bonding wires 25B is provided at an end of the plurality of second semiconductor memory chips 22B on the side in the −X direction.

In the present embodiment, each of the second bonding wires 25B is disposed on the side in the +X direction with respect to the relay component 60. One end of each of the second bonding wires 25B is bonded to the pad 31SB of the package board 21. Each of the second bonding wires 25B extends through the pads 41S of the plurality of second semiconductor memory chips 22B in order from the pad 31SB. In the present embodiment, each of the second bonding wires 25B extends through an area between the plurality of first semiconductor memory chips 22A and the plurality of second semiconductor memory chips 22B. Each of the second bonding wires 25B is connected to the pad 31SB. Each of the second bonding wires 25B is electrically connected to the relay component 60 via the package board 21.

In the present embodiment, at least some of the plurality of second bonding wires 25B overlap at least some of the plurality of first semiconductor memory chips 22A when viewed from the Z direction. For example, some of all the second bonding wires 25B overlap at least some of the first semiconductor memory chips 22A when viewed from the Z direction.

### <B2. Electrical Connection Structure Related to Relay Component>

Next, an electrical connection structure related to the relay component 60 will be described.

FIG. 12 is a cross-sectional view showing an enlarged area surrounded by a line F12 shown in FIG. 11. The plurality of connection terminals 62 of the relay component 60 include a predetermined number of (for example, 12) connection terminals 62SQ, a predetermined number of (for example, 12) connection terminals 62SA, and a predetermined number of (for example, 12) connection terminals 62SB. In FIG. 12, for convenience of description, only one connection terminal 62SQ, one connection terminal 62SA, and one connection terminal 62SB are shown.

In the present embodiment, the wiring pattern 21w of the package board 21 includes a plurality of signal lines 21wQ, a plurality of signal lines 21wA, and a plurality of signal lines 21wB. The predetermined number of connection terminals 62SQ and the predetermined number of connection terminals 27S of the NAND package 14′ are electrically connected in a one-to-one relationship via the plurality of signal lines 21wQ of the package board 21. The predetermined number of connection terminals 62SA and the plurality of pads 31SA of the package board 21 are electrically connected in a one-to-one relationship via the plurality of signal lines 21wA of the package board 21. The predetermined number of connection terminals 62SB and the plurality of pads 31SB of the package board 21 are electrically connected in a one-to-one relationship via the plurality of signal lines 21wB of the package board 21.

In the present embodiment, the predetermined number of connection terminals 62SA are disposed closer to the side in the −X direction compared to the predetermined number of connection terminals 62SQ. Note that, the “predetermined number of connection terminals 62SA are disposed closer to the side in the −X direction compared to the predetermined number of connection terminals 62SQ” means that, when the predetermined number of connection terminals 62SA is compared with the predetermined number of connection terminals 62SQ, the number of connection terminals 62SA located on the side in the −X direction is larger than the number of connection terminals 62SQ located on the side in the −X direction, and may also include a case in which one or a small number of connection terminals 62SA are located on the side in the +X direction compared to the connection terminals 62SQ.

In the present embodiment, the predetermined number of connection terminals 62SB are disposed closer to the side in the +X direction compared to the predetermined number of connection terminals 62SQ. Note that, “the predetermined number of connection terminals 62SB are disposed closer to the side in the +X direction compared to the predetermined number of connection terminals 62SQ” means that, when the predetermined number of connection terminals 62SB is compared with the predetermined number of connection terminals 62SQ, the number of connection terminals 62SB located on the side in the +X direction is larger than the number of connection terminals 62SQ located on the side in the +X direction, and may also include a case in which one or a small number of connection terminals 62SB are located on the side in the −X direction compared to the connection terminals 62SQ.

In the present embodiment, the predetermined number of connection terminals 62SA are disposed closer to the side in the −X direction compared to the predetermined number of connection terminals 62SB. Note that, “the predetermined number of connection terminals 62SA are disposed closer to the side in the −X direction compared to the predetermined number of connection terminals 62SB” means that, when the predetermined number of connection terminals 62SA is compared with the predetermined number of connection terminals 62SB, the number of connection terminals 62SA located on the side in the −X direction is larger than the number of connection terminals 62SB located on the side in the −X direction, and may also include a case in which one or a small number of connection terminals 62SA are located on the side in the +X direction compared to the connection terminals 62SB.

In the present embodiment, the relay component 60 includes the branching portion DP. At the branching portion DP, the path of the relay component 60 is branched into the path P1 that electrically connects the plurality of connection terminals 27S (the predetermined number of connection terminals 27S) included in the connection terminal 27 to the plurality of first bonding wires 25A, and the path P2 that electrically connects the plurality of connection terminals 27S (the predetermined number of connection terminals 27S) included in the connection terminal 27 to the plurality of second bonding wires 25B.

In the present embodiment, the branching portion DP includes the interface circuit 60a provided in the component body 61. In the present embodiment, the interface circuit 60a switches between a first state and a second state based on a signal received from the controller 12, for example. Here, the first state means a state in which the path P1 is connected and the path P2 is disconnected. The second state means a state in which the path P2 is connected and the path P1 is disconnected. In the first state, signals (for example, the data signal and the timing signal) are transmitted and received between the plurality of first semiconductor memory chips 22A and the controller 12. In the second state, signals (for example, the data signal and the timing signal) are transmitted and received between the plurality of second semiconductor memory chips 22B and the controller 12. In the present embodiment, an electrical connection relationship for two channels is realized by the first state and the second state. In the present embodiment, the electrical connection relationship for two channels is realized between the relay component 60 and the plurality of (for example, eight) semiconductor memory chips 22. On the other hand, an electrical connection relationship for one channel is realized between the relay component 60 and the package board 21 (that is, between the relay component 60 and the board 11).

### <B3. Advantages>

In the present embodiment, the NAND package 14′ includes the relay component 60 mounted on the package board 21. The relay component 60 includes the branching portion DP. With this configuration, it is possible to realize the branching portion DP using the relay component 60. This makes it easy to downsize the NAND package 14′ compared to a case in which a special additional component is provided inside the NAND package 14′.

In the present embodiment, the center C2 of the relay component 60 in the X direction is disposed to be displaced by 1 mm or more in the X direction with respect to the center C1 of the package board 21 in the X direction. With this configuration, it is possible to shorten a distance between the relay component 60 and the controller 12. When it is possible to shorten the distance between the relay component 60 and the controller 12, it becomes easy to increase the speed of the memory system 1.

In the present embodiment, the relay component 60 is a package component including the plurality of connection terminals 62, and is flip-chip mounted on the first surface 21a of the package board 21. With this configuration, it is possible to provide the branching portion DP using the relay component 60 that is capable of being flip-chip mounted and has excellent mountability.

In the present embodiment, the plurality of first semiconductor memory chips 22A are stacked on the relay component 60 from the side opposite to the package board 21. With this configuration, it is easier to downsize the NAND package 14′ in the X direction compared to a case when the plurality of first semiconductor memory chips 22A are not stacked on the relay component 60 (a case in which the plurality of first semiconductor memory chips 22A are stacked on the package board 21 at positions different from the relay component 60).

In the present embodiment, the plurality of first bonding wires 25A are disposed on the side in the −X direction with respect to the plurality of (for example, four) first semiconductor memory chips 22A. The plurality of second bonding wires 25B are disposed on the side in the −X direction with respect to a plurality of (for example, four) second semiconductor memory chips 22B. With such a configuration, it is possible to shorten a wiring distance between a plurality of (for example, eight) semiconductor memory chips 22 and the relay component 60 compared to, for example, a case in which the plurality of first bonding wires 25A are disposed on the side in the −X direction with respect to the plurality of first semiconductor memory chips 22A and the plurality of second bonding wires 25B are disposed on the side in the +X direction with respect to the plurality of second semiconductor memory chips 22B.

In the present embodiment, the plurality of second bonding wires 25B extend between the plurality of first semiconductor memory chips 22A and the plurality of second semiconductor memory chips 22B. With this configuration, it is possible to shorten a distance between the plurality of second semiconductor memory chips 22B and the controller 12, and it becomes easy to increase the speed of the memory system 1.

Several embodiments and modified examples have been described above. Note that, the embodiments and modified examples are not limited to the above-described examples. For example, the “semiconductor storage device” in the present application is not limited to the NAND package 14, but may be other types of semiconductor memory such as a NOR type memory, a magnetoresistive random access memory (MRAM), or a resistive memory. Further, the “semiconductor storage device” in the present application is not limited to a non-volatile semiconductor storage device, but may be a volatile semiconductor storage device such as a DRAM.

According to at least one embodiment described above, the semiconductor storage device includes a plurality of semiconductor memory chips and a plurality of connection terminals. Each of the plurality of semiconductor memory chips includes only a plurality of first terminals for one channel configured of a predetermined number of terminals, and the plurality of first terminals serve as the terminals capable of transferring data signals or timing signals. The plurality of connection terminals include only a plurality of second terminals for one channel configured of the predetermined number of terminals, and the plurality of second terminals serve as the terminals capable of transferring data signals or timing signals. This makes it possible to improve electrical characteristics of the memory system.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a first board;
a control circuit on the first board; and
a semiconductor storage device on the first board, wherein
the semiconductor storage device includes:
a second board including a first surface and a second surface, the second surface being on a side opposite to the first surface;
a sealing member covering the first surface when viewed from a thickness direction of the second board;
a plurality of semiconductor memory chips between the first surface and the sealing member;
a plurality of bonding wires connecting the first surface to the plurality of semiconductor memory chips; and
a plurality of connection terminals on the second surface and connected to the first board, wherein
each of the plurality of semiconductor memory chips includes only a plurality of first terminals for one channel configured of a predetermined number of terminals,
the plurality of first terminals serve as terminals capable of transferring data signals or timing signals,
the plurality of connection terminals include only a plurality of second terminals for one channel configured of the predetermined number of terminals, and
the plurality of second terminals serve as terminals capable of transferring the data signals or the timing signals.

2. The memory system according to claim 1, wherein
the plurality of semiconductor memory chips include a plurality of first semiconductor memory chips and a plurality of second semiconductor memory chips,
the plurality of bonding wires include a plurality of first bonding wires and a plurality of second bonding wires,
the plurality of first bonding wires are connected to the plurality of first terminals of each of the plurality of first semiconductor memory chips,
the plurality of second bonding wires are connected to the plurality of first terminals of each of the plurality of second semiconductor memory chips,
the semiconductor storage device includes a branching portion, a first path, and a second path,
the first path electrically connects the plurality of second terminals to the plurality of first bonding wires,
the second path electrically connects the plurality of second terminals to the plurality of second bonding wires, and
the first path and the second path are branched at the branching portion.

3. The memory system according to claim 2, wherein
the second board includes the branching portion.

4. The memory system according to claim 3, wherein
the branching portion includes a plurality of pads on the first surface,
the plurality of first bonding wires are connected to the plurality of pads, and
the plurality of second bonding wires are connected to the plurality of pads electrically in parallel with the plurality of first bonding wires.

5. The memory system according to claim 2, wherein
the semiconductor storage device further includes a relay component on the second board, and
the relay component includes the branching portion.

6. The memory system according to claim 5, wherein
the plurality of first bonding wires are connected to the second board and electrically connected to the relay component via the second board, and
the plurality of second bonding wires are connected to the second board and electrically connected to the relay component via the second board.

7. The memory system according to claim 6, wherein
when a direction along the first surface is defined as a first direction,
a center of the relay component in the first direction is displaced by 1 mm or more in the first direction with respect to a center of the second board in the first direction.

8. The memory system according to claim 6, wherein
when a direction along the first surface is defined as a first direction, a center of the relay component in the first direction is displaced to a side closer to the control circuit with respect to a center of the second board in the first direction.

9. The memory system according to claim 5, wherein
the relay component is a package component including a plurality of terminals and is flip-chip mounted on the first surface, and
the plurality of first semiconductor memory chips are stacked on the relay component from a side opposite to the second board.

10. The memory system according to claim 9, wherein
the plurality of second bonding wires extend between the plurality of first semiconductor memory chips and the plurality of second semiconductor memory chips, and
at least some of the plurality of second bonding wires overlap at least some of the first semiconductor memory chips of the plurality of first semiconductor memory chips when viewed from the thickness direction of the second board.

11. The memory system according to claim 1, wherein
when the direction along the first surface is defined as a first direction,
the plurality of second terminals include a first number of second terminals and a second number of second terminals,
with respect to a center of the second board in the first direction, the second terminals are on a side closer to the control circuit and the second terminals are on a side farther from the control circuit, and
the first number is larger than the second number.

12. A semiconductor storage device comprising:
a second board including a first surface and a second surface, the second surface being on a side opposite to the first surface;
a sealing member covering the first surface when viewed from a thickness direction of the second board;
a plurality of semiconductor memory chips between the first surface and the sealing member;
a plurality of bonding wires connecting the first surface to the plurality of semiconductor memory chips; and
a plurality of connection terminals on the second surface, wherein
each of the plurality of semiconductor memory chips includes only a plurality of first terminals for one channel configured of a predetermined number of terminals,
the plurality of first terminals serve as terminals capable of transferring data signals or timing signals; and
the plurality of connection terminals include only a plurality of second terminals for one channel configured of the predetermined number of terminals, and
the plurality of second terminals serve as terminals capable of transferring the data signals or the timing signals.

13. The semiconductor storage device according to claim 12, wherein
the plurality of semiconductor memory chips include a plurality of first semiconductor memory chips and a plurality of second semiconductor memory chips,
the plurality of bonding wires include a plurality of first bonding wires and a plurality of second bonding wires,
the plurality of first bonding wires are connected to the plurality of first terminals of each of the plurality of first semiconductor memory chips,
the plurality of second bonding wires are connected to the plurality of first terminals of each of the plurality of second semiconductor memory chips,
the semiconductor storage device includes a branching portion, a first path, and a second path,
the first path electrically connects the plurality of second terminals to the plurality of first bonding wires,
the second path electrically connects the plurality of second terminals to the plurality of second bonding wires, and
the first path and the second path are branched at the branching portion.

14. The semiconductor storage device according to claim 13, wherein
the second board includes the branching portion.

15. The semiconductor storage device according to claim 14, wherein
the branching portion includes a plurality of pads on the first surface,
the plurality of first bonding wires are connected to the plurality of pads, and
the plurality of second bonding wires are connected to the plurality of pads electrically in parallel with the plurality of first bonding wires.

16. The semiconductor storage device according to claim 13, further comprising: a relay component on the second board, wherein
the relay component includes the branching portion.

17. The semiconductor storage device according to claim 16, wherein
the plurality of first bonding wires are connected to the second board and electrically connected to the relay component via the second board, and
the plurality of second bonding wires are connected to the second board and electrically connected to the relay component via the second board.

18. The semiconductor storage device according to claim 17, wherein
when a direction along the first surface is defined as a first direction,
a center of the relay component in the first direction is displaced by 1 mm or more in the first direction with respect to a center of the second board in the first direction.

19. The semiconductor storage device according to claim 12, wherein
when the direction along the first surface is defined as a first direction,
the plurality of second terminals include a first number of second terminals and a second number of second terminals,
with respect to a center of the second board in the first direction, the second terminals are on a side closer to a control circuit and the second terminals are on a side farther from the control circuit, and
the first number is larger than the second number.

20. The semiconductor storage device according to claim 16, wherein
the relay component is a package component including a plurality of terminals and is flip-chip mounted on the first surface, and
the plurality of first semiconductor memory chips are stacked on the relay component from a side opposite to the second board.
